(19) United States
(12) Patent Application Publication
(10) Pub. No.: US 2013/0104985 A1
(43) Pub. Date: May 2, 2013

(54) PHOTOVOLTAIC DEVICE WITH MANGENESE AND TELLURIUM INTERLAYER

(71) Applicants: Bastiaan Arie Korevaar, Schenectady, NY (US); James William Bray, Niskayuna, NY (US)

(72) Inventors: Bastiaan Arie Korevaar, Schenectady, NY (US); James William Bray, Niskayuna, NY (US)

(73) Assignee: GENERAL ELECTRIC COMPANY, SCHENECTADY, NY (US)

(21) Appl. No.: 13/286,794

(22) Filed: Nov. 1, 2011

(51) Int. Cl. H01L 31/0264

(52) U.S. Cl. 136/260

(57) ABSTRACT

A photovoltaic device includes an absorber layer comprising a material comprising cadmium and tellurium. The photovoltaic device further includes a p+-type semiconductor layer and an interlayer interposed between the absorber layer and the p+-type semiconductor layer. The interlayer comprises manganese. The photovoltaic device may be manufactured as a substrate-based device or as a superstrate base device.

### BACKGROUND

The invention relates generally to photovoltaic (PV) cells and, more particularly, to photovoltaic cells with improved back contacts.

PV (or solar) cells are used for converting solar energy into electrical energy. Typically, in its basic form, a PV cell includes a semiconductor junction made of two or three layers that are disposed on a substrate layer, and two contacts (electrically conductive layers) for passing electrical energy in the form of electrical current to an external circuit. Moreover, additional layers are often employed to enhance the conversion efficiency of the PV device.

There are a variety of candidate material systems for PV cells, each of which has certain advantages and disadvantages. Cadmium telluride (CdTe) is a prominent polycrystalline thin-film material, with a nearly ideal bandgap of about 1.45-1.5 electron volts. CdTe also has a very high absorptivity, and films of CdTe can be manufactured using low-cost techniques. In theory, solar cell efficiencies in excess of twenty percent (20%) could be achieved for cadmium sulfide (CdS)/CdTe devices, provided various issues with the quality of the individual semiconductor layers and with the back contact electrode can be overcome.

However, cadmium telluride (CdTe)-based photovoltaic devices typically demonstrate relatively low power conversion efficiencies, which may be attributed to a relatively low open circuit voltage (V_{oc}) in relation to the band gap of the material which is due, in part, to the low effective carrier concentration and short minority carrier lifetime in CdTe. The short minority carrier lifetime that is typically exhibited by thin film CdTe devices may be attributed to the high defect density that occurs when thin film CdTe is grown at relatively low temperatures (500-550° C.) using close-spaced sublimation (or CSS) or similar types of deposition systems. The high defect density results in the presence of donor and acceptor states that offset each other, resulting in an effective carrier density in the 10¹² to 10¹⁵ per cubic centimeter (cc) range for CdTe.

Additionally, there is an increased drive for decreasing the thickness of the CdTe layer because of the concern around availability of tellurium and also increased interest in photovoltaic devices with “n-i-p” configuration. However, thinner CdTe layer may lead to recombination of electron-hole pairs at the back contact and lower open circuit voltage. Thus, minimizing the recombination of the electron/hole pairs at the back contact layer in thin film CdTe photovoltaic cells may be desirable.

Further issues with improving the cell efficiency of CdTe solar cells include the high work function of CdTe. The high work function of CdTe allows a narrow choice of metals that can be employed to form an Ohmic back contact with the CdTe layer. One approach to improve the back-contact resistance includes increasing the carrier concentration in the regions near the contact points of the CdTe layer and the back contact layer, wherein the back contact layer is a metal layer. For example, for a p-type CdTe material, increasing the carrier concentration amounts to increasing the p-type carriers in the CdTe material to form a “p+ layer” on the backside of the CdTe layer, which is in contact with the back contact layer. However, typical methods employed to form the p+ layers may pose drawbacks such as, for example, diffusion of metal, like Cu, through CdTe causing degradation.

Thus, there is a need to provide improved back contact layer configuration to provide improved interfaces and to minimize recombination of electron/hole pairs at the back contact. Further, there is a need to provide cost-effective photovoltaic devices having improved back contact to provide the desired power conversion efficiencies.

### BRIEF DESCRIPTION

One aspect of the present invention resides in a photovoltaic device that includes an absorber layer comprising a material comprising cadmium and tellurium. The photovoltaic device further includes a p+-type semiconductor layer and an interlayer interposed between the absorber layer and the p+-type semiconductor layer. The interlayer comprises manganese.

Another aspect of the present invention resides in a photovoltaic device that includes an absorber layer comprising a material comprising cadmium and tellurium. The photovoltaic device further includes a p+-type semiconductor layer and an interlayer interposed between the absorber layer and the p+-type semiconductor layer. The interlayer comprises manganese and tellurium, and the interlayer comprises a composition having a formula (I):

Cdᵢ₋ₓMnₓTe, (I)

where “x” is in a range from about 0.01 to about 0.6. The photovoltaic device further includes a first electrically conductive layer, where the p+-type semiconductor layer is disposed between the first electrically conductive layer and the interlayer. The photovoltaic device further includes a window layer, where the absorber layer is disposed between the window layer and the interlayer. The photovoltaic device further includes a second electrically conductive layer, where the window layer is disposed between the second electrically conductive layer and the absorber layer.

### DRAWINGS

These and other features, aspects, and advantages of the present invention will become better understood when the following detailed description is read with reference to the accompanying drawings in which like characters represent like parts throughout the drawings, wherein:

FIG. 1 schematically depicts semiconductor layers within a photovoltaic device;

FIG. 2 schematically depicts a photovoltaic device with a superstrate configuration;

FIG. 3 schematically depicts a photovoltaic device with an optional buffer layer and having a superstrate configuration; and

FIG. 4 schematically depicts a photovoltaic device with a substrate configuration.

### DETAILED DESCRIPTION

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The modifier “about” used in connection with a quantity is inclusive of the stated value, and has the meaning dictated by context, (e.g., includes the degree of error associated with measurement of the particular quantity). In addition, the term “combination” is inclusive of blends, mixtures, alloys, reaction products, and the like.

Moreover, in this specification, the suffix “(s)” is usually intended to include both the singular and the plural of the term that it modifies, thereby including one or more of that term. Reference throughout the specification to “one embodiment,” or “another embodiment,” “an embodiment,” and so forth, means that a particular element (e.g., feature, structure, and/or characteristic) described in connection with the embodiment is included in at least one embodiment described herein, and may or may not be present in other embodiments. Similarly, reference to “a particular configuration” means that a particular element (e.g., feature, structure, and/or characteristic) described in connection with the configuration is included in at least one configuration described herein, and may or may not be present in other configurations. In addition, it is to be understood that the described inventive features may be combined in any suitable manner in the various embodiments and configurations.

In addition, approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

Further, the terms “transparent region”, “transparent layer” and “transparent electrode” as used herein, refer to a region, a layer, or an article that allows an average transmission of at least 80% of incident electromagnetic radiation having a wavelength in a range from about 300 nm to about 850 nm. As used herein, the term “disposed on” refers to layers disposed directly in contact with each other or indirectly by having intervening layers there between.

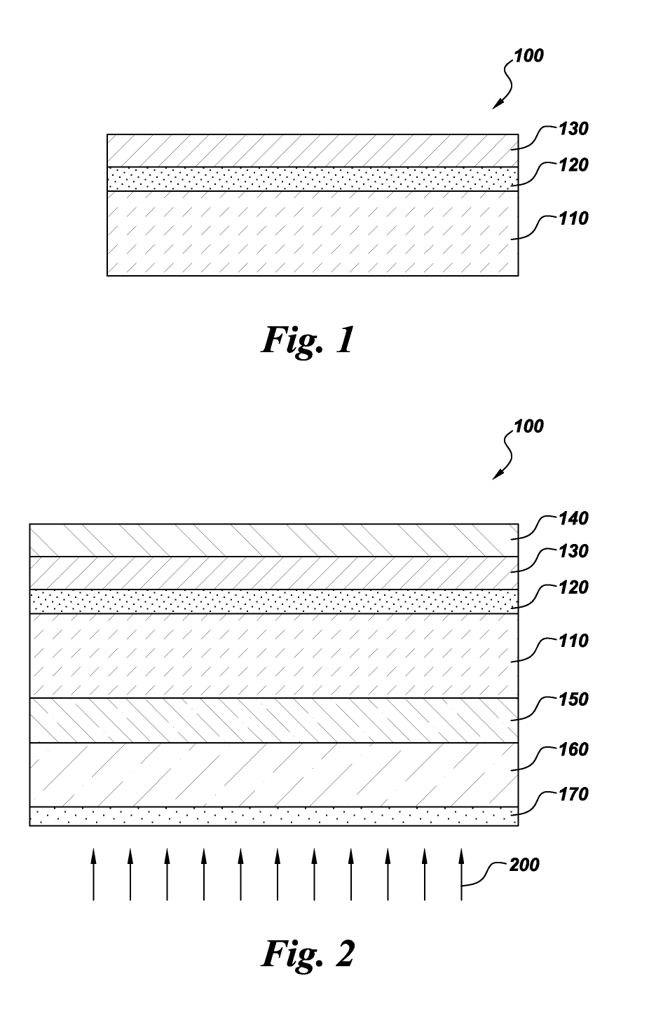

A photovoltaic device 100 is described with reference to FIGS. 1-4. As indicated in FIGS. 1-4, the photovoltaic device 100 includes an absorber layer 110 comprising a material comprising cadmium and tellurium. Typically, when solar radiation is incident on the photovoltaic device 100, electrons in the absorber layer 110 are excited from a lower energy “ground state,” in which they are bound to specific atoms in the solid, to a higher “excited state,” in which they can move through the solid. Because most of the energy in sunlight and artificial light is in the visible range of electromagnetic radiation, a solar cell absorber should be efficient in absorbing radiation at those wavelengths.

For particular configurations, the absorber layer 110 comprises a material selected from the group consisting of cadmium telluride, cadmium zinc telluride, cadmium sulfur telluride, cadmium manganese telluride, cadmium magnesium telluride and combinations thereof, and wherein the window layer (24) comprises a material selected from the group consisting of cadmium sulfide (CdS), indium (III) sulfide (In₂S₃), zinc sulfide (ZnS), zinc telluride (ZnTe), zinc selenide (ZnSe), cadmium selenide (CdSe), cadmium manganese selenide (CdₓMn₁₋ₓSe), oxygenated cadmium sulfide (CdS:O), copper oxide (Cu₂O), amorphous or micro-crystalline silicon and Zn(O,H) and combinations thereof. These materials should also be understood to include the alloys thereof. For example, CdTe can be alloyed with zinc, magnesium, manganese, and/or sulfur to form cadmium zinc telluride, cadmium copper telluride, cadmium manganese telluride, cadmium magnesium telluride and combinations thereof. It bears noting that the above-mentioned photo-active semiconductor materials may be used alone or in combination. Further, these materials may be present in more than one layer, each layer having different type of photo-active material or having combinations of the materials in separate layers.

For particular configurations, the absorber layer 110 comprises a p-type material, for example p-type CdTe, and has a thickness less than about three (3) μm and, more particularly, has a thickness less than about two (2) μm, and less than about 1.5 μm for certain configurations. The materials listed above may be actively doped to be p-type. Suitable dopants vary based on the semiconductor material. For CdTe, suitable p-type dopants include, without limitation, copper, gold, nitrogen, phosphorus, antimony, arsenic, silver, bismuth, and sodium.

Referring again to FIGS. 1-4, the photovoltaic device 100 further includes a p+-type semiconductor layer 130. The term “p+-type semiconductor layer” as used herein refers to a semiconductor layer having an excess mobile p-type carrier or hole density compared to the p-type charge carrier or hole density in the absorber layer 110. As used herein, the term “carrier density” refers to the concentration of holes or electrons in a material. For particular arrangements, the p+-type semiconductor layer has a p-type carrier density in a range greater than about 1×10¹⁷ per cubic centimeter (cc) and, more particularly, has a p-type carrier density in a range greater than about 5×10¹⁷ per cc and still more particularly has a p-type carrier density in a range greater than about 10¹⁸ per cc, and more particularly has a p-type carrier density in a range greater than about 10¹⁹ per cc. For certain arrangements, the p+-type semiconductor layer has a p-type carrier density in a range from about 10¹⁷ per cc to about 10²⁰ per cc. Beneficially, the p+-type semiconductor layer 130 may serve as an interface between the absorber 110 and the first electrically conductive layer 140 (described below). For the superstrate-based PV device shown in FIG. 2, higher carrier densities for the p+-type semiconductor layer 130 may beneficially reduce the series resistance of the back contact layer 140, as compared to other resistances within the PV device. For example configurations, the p+-type semiconductor layer has a thickness in a range from about 20 nm to about 200 nm.

Example materials for the p+-type semiconductor layer 130 include, without limitation, a doped p-type material selected from the group consisting of amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, (LaSr)CuOS, LaCuOSe_{0.6}Te_{0.4}, BiCuOSe, (BiCa)CuOSe, PrCuOSe, NdCuOS, Sr₂Cu₂ZnO₂S₂, Sr₂CuGaO₃S, (Ni,Zn,Co)₃O₄, and combinations thereof.

For other arrangements, the p+-type semiconductor layer 130 may comprise a doped p+-doped material selected from the group consisting of zinc telluride, beryllium telluride, mercury telluride, arsenic telluride, antimony telluride, copper telluride, cadmium telluride, and combinations thereof. The p+-doped material may further include a dopant selected from the group consisting of copper, gold, nitrogen, phosphorus, antimony, arsenic, silver, bismuth, sulfur, sodium, and combinations thereof. For particular configurations, the p+-type semiconductor layer 130 may have a thickness in a range from about 50 nm to about 200 nm.

Depending on the specific material selected, as well as the dopant type and concentration thereof, the p+-type semiconductor layer 130 may have a band gap (E_{g}) in a range from about 1.5 electron Volts (eV) to about 3.5 eV, and more particularly, in a range from about 1.5 eV to about 2.0 eV and still more particularly. in a range from about 1.8 eV to about 1.9 eV. In yet another embodiment, the p+-type semiconductor layer 130 has a band gap in a range from about 2.5 electron Volts to about 3.5 electron Volts. As mentioned above, the material, dopant and concentration thereof for the p+-type semiconductor layer 130 may be selected such that the band gap of the p+-type semiconductor layer 130 may be greater than or equal to the band gap of the absorber 110.

Referring again to FIGS. 1-4, the photovoltaic device 100 further includes an interlayer 120 interposed between the absorber layer 110 and the p+-type semiconductor layer 130. The interlayer 120 comprises manganese. More particularly, the interlayer 120 comprises manganese and tellurium. Still more particularly, the interlayer 120 may comprise a composition having a formula (I):

Cd₁₋ₓMnₓTe, (I)

where “x” is in a range from about 0.01 to about 0.60, and, more particularly, “x” may be in a range from about 0.05 to about 0.44, and still more particularly, in a range of about 0.1-0.2. Beneficially, a combination of the interlayer 120, the p+-type semiconductor layer 130, and the first electrically conductive layer 140 (described below) may provide for an improved back contact in the photovoltaic device 100.

For particular configurations, the interlayer 120 may further include one or more suitable dopants, non-limiting examples of which include Cd vacancies, N and P (for p-type) and Cd, In, Al, and Ga (for n-type). For certain arrangements, the interlayer 120 may comprise a graded manganese concentration, that is, the concentration of manganese may vary across the thickness of the interlayer. In some configurations, the concentration of the dopant and manganese may be selected, such that the interlayer has a higher band gap than the absorber and functions as an electron reflector layer into the absorber layer, especially if the mismatch in the band gaps at the interlayer/absorber layer interface is such that the conduction band level of the interlayer is significantly above that of the absorber layer.

The composition of the interlayer 120 may be selected to advantageously match the lattice constants of the interlayer and the absorber 110. For example, the composition of the interlayer 120 may be selected to advantageously match the lattice constants of the interlayer and the CdTe in the absorber layer 110. For particular configurations, the composition of the interlayer 120 may be selected such that the percentage difference between the lattice constant of the absorber layer 110 and the lattice constant of the interlayer 120 is less than about one percent (1%), and more particularly is less than about 0.1%, and still more particularly, is substantially the same. Without being bound by any theory, it is believed that improved lattice matching between the two layers may result in reduced interfacial defects between the layers, which may be desirable to increase the carrier lifetimes near the back-contact. When making the CdTe absorber layer thinner, interface recombination will increasingly become more important and thus lattice matching the back-contact material also becomes more critical, as it reduces deleterious interface states. Beneficially, MnTe has a very good lattice match to CdTe and is a suitable back-contact buffer layer for improved performance.

For particular configurations, the interlayer 120 comprises manganese telluride (MnTe). For embodiments employing CdTe as the absorber layer 110, the use of MnTe as the interlayer 120 may advantageously provide for an improved interface having minimal defects because the lattice constant of MnTe is well-matched to the lattice constant of CdTe (that is, their crystal structure and lattice constant are substantially similar). In particular, because the lattice constant of MnTe is well-matched to the lattice constant of CdTe up to about 44 cation atomic percent of Mn. For other arrangements, the interlayer 120 may comprise ternary manganese cadmium telluride, which may further reduce strain at the interlayer 120 and the first semiconductor layer 110 interface. In addition, for particular configurations for which the interlayer 120 comprises manganese, MnSe may be disposed between a CdTe (p or n) absorber layer and the p+-type semiconductor layer 130.

Commonly assigned U.S. patent application Ser. No. 13/018,650, Korevaar et al., “Photovoltaic Device,” which is incorporated by reference herein in its entirety, discloses the use of MgTe to form an interlayer for CdTe PV devices. However, MnTe has a slightly lower bandgap (3.4 e V for MnTe, as compared to 3.7 eV for MgTe, at room temperature) and can therefore be doped a bit better. The other advantage is that fluctuations in manganese content have less impact on the band-structure than do fluctuations in magnesium content. CdMnTe is also believed to be more temperature stable than CdMgTe in the event that subsequent heat-treatments are necessary after the interlayer has been formed, e.g., in a substrate-based approach.

For certain configurations, the interlayer may comprise a p-type material or an intrinsic material. For particular configurations, the interlayer 120 comprises a lightly 10¹³-10¹⁵/cc doped p-type material. For example, the interlayer 120 may comprise a p-doped manganese telluride or a p-doped cadmium manganese telluride. Desirably, the composition and/or dopant concentration may be selected to tailor the band gap offset (ΔE_{g}) between the absorber layer and the interlayer to result in charge separation and thus reduce recombination of electron/hole pairs at the back contact (described below) of the PV device. For certain configurations, the combination of a lightly doped p-type interlayer 120 and the p+-type semiconductor layer 130 may result in depletion of the interlayer 120, and create an electric field into the absorber layer 110. For certain configurations, a combination of a lightly doped p-type interlayer 120 and the p+-type semiconducting layer may provide for an improved back contact having reduced electron/hole pair recombination.

To avoid formation of a potential barrier at the interface between the interlayer 120 and the absorber layer 110, the composition of the interlayer 120 may be selected to avoid a bandgap discontinuity between the interlayer 120 and the absorber layer 110. For example, the composition of the interlayer 120 may be further selected such that the band gap of the interlayer 120 is greater than or equal to the band gap of the absorber layer 110. For particular configurations, the interlayer 120 has a band gap E_{g} in a range from about 1.6 eV to about 2.2 eV. In addition, for particular configurations, the interlayer 120 has a thickness in a range from about 20 nm to about 200 nm and more particularly, in a range of about 20-100 nm, and more particularly, in a range of about 20-50 nm.

Beneficially, the interlayer may provide an interface with a low concentration of defect states between the absorber layer and the p+-type semiconductor layer. Further, by tailoring the composition and controlling the deposition of the interlayer, the lattice constant of the interlayer may substantially match the lattice constant of the absorber layer material, thus forming an improved interface. The lattice matching of the interlayer and the absorber layer may be particularly desirable for thin film CdTe devices, such as, for example, photovoltaic devices having “n-i-p” configuration, as it reduces strain in the two layers and thereby reduces defects.

As noted above, the interlayer may be p-doped, such that the interlayer advantageously functions as a separation layer between the holes and the electrons and thus minimizes recombination of electron/hole pairs at the back contact. For certain thin film CdTe photovoltaic devices with “n-i-p” configurations, a combination of a p-type interlayer and the absorber layer may advantageously provide for an improved back contact having reduced electron/hole pair recombination. Thus, the use of the interlayer 120 may advantageously provide for an improved interface at the back-side of the CdTe absorber layer, reducing the recombination rate at that interface, providing a low recombining back contact for photovoltaic devices employing thin CdTe layers, such as, for example having a thickness in a range less than about 2 microns. Accordingly, the interlayer may advantageously facilitate the use of thinner CdTe layers in photovoltaic devices.

For the example configuration shown in FIG. 2, the photovoltaic device 100 of further includes a window layer 150. The window layer 150 is the junction-forming layer for the photovoltaic device 100, for the configurations shown in FIGS. 2-4. The addition of the window layer 150 induces an electric field that produces the photovoltaic effect. As indicated in FIG. 2, the absorber layer 110 is disposed between the window layer 150 and the interlayer 120. Example materials for the window layer 150 include, without limitation, cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), amorphous or micro-crystalline silicon and Zn(O,H) and combinations thereof. According to a particular embodiment, the window layer 150 comprises CdS and has a thickness in a range of about 50-100 nm. The atomic percent of cadmium in the cadmium sulfide, for certain configurations, is in a range of about 45-55 atomic percent, and more particularly, in a range of about 48-52 atomic percent. For the arrangements shown in FIGS. 1-4, the window and absorber layers 150, 110 form a heterojunction. As used in this context, a heterojunction is a semiconductor junction that is composed of layers of dissimilar semiconductor materials. These materials usually have non-equal band gaps. As an example, a heterojunction can be formed by contact between a layer or region of one conductivity type with a layer or region of opposite conductivity, e.g., a “p-n” junction, which when exposed to appropriate illumination, generates a photovoltaic current, for these photoactive materials.

In addition to the p-type absorber layer 110 described above, for other configurations, the absorber 110 may comprise a substantially intrinsic semiconductor material (i-type). As used herein, the term “substantially intrinsic” refers to a semiconductor material having a carrier density of less than about 5×10¹³ per cc, or more particularly, less than about 2×10¹³ per cc, or still more particularly, less than about 1×10¹³ per cc. As will be recognized by those skilled in the art, carrier concentrations in this range may be achieved for both actively doped material and material formed without the active introduction of dopants. For certain configurations, the window layer 150 (described below) may be doped to be n-type, and the absorber 110, the window layer 150, and the interlayer 120 may form a “p-i-n” or “n-i-p” junction. As known in the art, carrier pairs generated in the substantially intrinsic absorber layer 110 are separated by an internal electric field generated by the respective doped layers, so as to create the photovoltaic current. In this manner, the n-i-p structure, when exposed to appropriate illumination, generates a photovoltaic current, which is collected by the electrically conductive layers 140 and 170 (described below), which are in electrical communication with appropriate layers of the photovoltaic device.

Example substantially intrinsic materials for the absorber layer 110 include, without limitation, cadmium telluride, cadmium zinc telluride, cadmium sulfur telluride, cadmium manganese telluride, cadmium magnesium telluride, and combinations thereof. The composition for the substantially intrinsic material may be selected such that the absorber layer 110 has a band gap in a range of about 1.3-1.6 eV, and more particularly, in a range of about 1.35-1.55 eV, and still more particularly, in a range of about 1.4-1.5 eV. Further, the composition for the substantially intrinsic material may be selected such that the band gap of the p+-type semiconductor layer 130 is greater than or equal to the band gap of the absorber layer 110. In addition, the composition for the substantially intrinsic material may be selected such that the band gap of the interlayer 120 is greater than or equal to the band gap of the absorber layer 110.

Referring again to FIG. 2, for the illustrated configuration, the photovoltaic device 100 further includes a first electrically conductive layer 140. As indicated in FIG. 2, the p+-type semiconductor layer 130 is disposed between the first electrically conductive layer 140 and the interlayer 120, and the p+-type semiconductor layer 130 may provide for improved diffusion properties between the first electrically conductive metal layer 140 and the absorber layer 110. Example materials for the first electrically conductive layer 140 include, without limitation gold, platinum, molybdenum, aluminum, chromium, nickel, and silver. In addition, for certain configurations, another metal layer (not shown), for example, aluminum, may be disposed on the first electrically conductive layer 140 to provide lateral conduction to the outside circuit. For the arrangement shown in FIG. 2, the first electrically conductive layer 140 is the back contact for the superstrate-based PV device 100. For the arrangement shown in FIG. 4, the first electrically conductive layer 140 is the front contact for the substrate-based PV device (which is also identified by reference numeral 100).

In addition, for the configuration shown in FIG. 2, the photovoltaic device 100 further includes a window layer 150. As discussed above, the absorber layer 110 is disposed between the window layer 150 and the interlayer 120. As indicated in FIG. 2, the photovoltaic device 100 further includes a second electrically conductive layer 160. The window layer 150 is disposed between the second electrically conductive layer 160 and the absorber layer 110. The second electrically conductive layer 160 may comprise a transparent conductive oxide (TCO). Example materials for the second electrically conductive layer 160 include, without limitation cadmium tin oxide (CTO), indium tin oxide (ITO), zinc tin oxide, fluorine-doped tin oxide (SnO:F or FTO), indium-doped cadmium oxide, cadmium stannate (Cd₂SnO₄ or CTO), and doped zinc oxide (ZnO), such as aluminum-doped zinc oxide (ZnO:Al or AZO), indium zinc oxide (IZO), and zinc tin oxide (ZnSnOₓ), or combinations thereof. Depending on the specific TCO employed (and on its sheet resistance), the thickness of the second electrically conductive layer 160 may be in a range of about 50 nm to about 300 nm. For the arrangement shown in FIG. 2, the second electrically conductive layer 160 is the front contact for the superstrate-based PV device 100. For the arrangement shown in FIG. 4, the second electrically conductive layer 160 is the back contact for the substrate-based PV device (which is also identified by reference numeral 100).

For the configuration shown in FIG. 2, the photovoltaic device 100 further includes a support 170. As indicated in FIG. 2, the second electrically conductive layer 160 is disposed between the support 170 and the window layer 150. More particularly, for the superstrate-based PV device 100 schematically depicted in FIG. 2, the support 170 has been subjected to a number of high temperature processing steps during the manufacture of the PV device. For particular configurations, the support 170 is transparent over the range of wavelengths for which transmission through the support 170 is desired. In one embodiment, the support 170 may be transparent to visible light having a wavelength in a range from about 400 nm to about 1000 nm. For particular configurations, the support 110 includes a material capable of withstanding heat treatment temperatures greater than about 600° C., such as, for example, silica or borosilicate glass. The support 110 may include a material that has a softening temperature lower than 600° C., such as, for example, soda-lime glass. For particular configurations, certain other layers may be disposed between the second electrically conductive layer 160 and the support 170, such as, for example, a reflective layer (not shown).

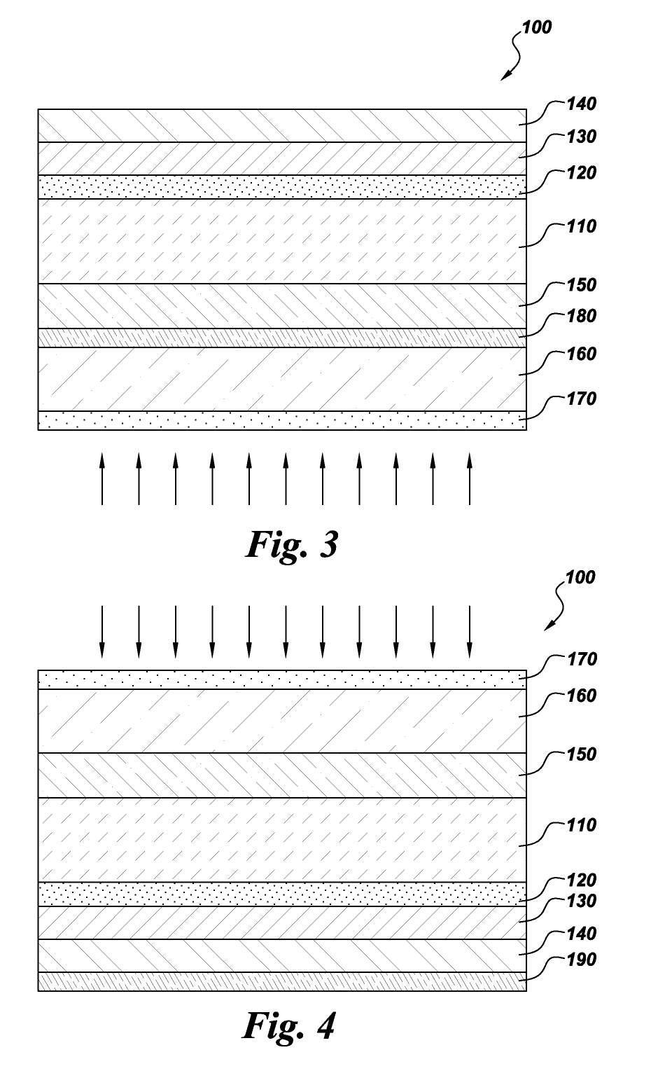

Similarly, for the configuration shown in FIG. 3, the photovoltaic device 100 further includes a support 170, where the first electrically conductive layer 140 is disposed between the support 170 and the p+-type semiconductor layer 130, and a cover 190. The second electrically conductive layer 160 is disposed between the cover 190 and the window layer 150. More particularly, for the substrate-based PV device schematically depicted in FIG. 4, the cover 190 may be affixed to the front contact 160 after the rest of the PV device 100 has been manufactured. For example the cover 190 may be adhered to the front contact 160 either directly or to an intermediate layer (not shown) by means of an adhesive. Accordingly, for the substrate-based PV device, the cover 190 is typically not subjected to multiple high temperature semiconductor processing steps during the manufacture of the PV device.

In addition, the photovoltaic device 100 may further optionally include a buffer layer 180, for example, a high resistance transparent conductive oxide (HRT) layer 180, interposed between the window layer 150 and the second electrically conductive layer 160, as indicated in FIG. 3. The thickness of the buffer layer 180 may be in a range of about 50-100 nm. Non-limiting examples of suitable materials for the buffer layer 180 include tin dioxide (SnO₂), zinc tin oxide (ZTO), zinc-doped tin oxide (SnO₂:Zn), zinc oxide (ZnO), indium oxide (In₂O₃), and combinations thereof.

As indicated for example in FIGS. 1-4, example photovoltaic devices 100, in accordance with aspects of the present invention, may include an absorber layer 110 comprising a material comprising cadmium and tellurium, a p+-type semiconductor layer 130, and an interlayer 120 interposed between the absorber layer 110 and the p+-type semiconductor layer 130. Suitable materials for the absorber layer 110 and p+-type semiconductor layer 130 are described above. The interlayer 120 comprises manganese and tellurium, and may comprise a composition having a formula (I):

Cd₁₋ₓMnₓTe, (I)

where “x” is in a range from about 0.01 to about 0.6.

The example photovoltaic devices 100 shown in FIGS. 2-4 further include a first electrically conductive layer 140, where the p+-type semiconductor layer 130 is disposed between the first electrically conductive layer 140 and the interlayer 120, and a window layer 150. As indicated in FIGS. 2-4, the absorber layer 110 is disposed between the window layer 150 and the interlayer 120. Suitable materials for the window layer 150 and the first electrically conductive layer 140 are described above. In addition, the example photovoltaic devices 100 shown in FIGS. 2-4 further include a second electrically conductive layer 160, where the window layer 150 is disposed between the second electrically conductive layer 160 and the absorber layer 110. Suitable materials for the second electrically conductive layer 160 are described above. In addition, the example photovoltaic devices 100 may optionally include a buffer layer 180, for example an HRT layer 180, as indicated in FIG. 3.

Although not expressly shown, the photovoltaic device 100 may be configured for an n-type CdTe absorber layer, and for this configuration the light may be incident on the first electrically conductive layer 140 (instead of, or in addition to the second electrically conductive layer, as shown in FIGS, 2 and 3.) However, the device structure will be similar to that shown in FIGS. 2 and 3. Namely, and as indicated in FIGS. 2 and 3, the photovoltaic device 100 further includes a first electrically conductive layer 140, where the p+-type semiconductor layer 130 is disposed between the first electrically conductive layer 140 and the interlayer 120. For this configuration, the first electrically conductive layer 140 may comprise a p-type TCO layer 140, for example. For still other arrangements, the p-type TCO 140 can be replaced with n-type TCO and a thin p+-region (not shown) or nano-wire collectors (not shown) may be employed, as described in commonly assigned US Patent Application Pub. No. 2011/0146744, Korevaar et al., “Photovoltaic cell,” which is incorporated by reference herein in its entirety. Further, for this configuration, the interlayer 120 functions as a front-contact buffer layer, and the p+-type semiconductor layer 130 and n-type absorber layer 110 form the PN junction for the PV device. For this configuration, the PV device further includes a semiconductor layer 150, where the n-type absorber layer 110 is disposed between the semiconductor layer 150 and the interlayer 120, as indicated in FIGS. 2 and 3. The semiconductor layer 150 may comprise CdS, for example, and for this configuration, the CdS layer 150 functions as a back-contact buffer layer. In addition, the PV device may optionally further include an HRT layer 180, as indicated in FIG. 3. For this n-type absorber configuration, the PV device further includes a second electrically conductive layer 160, wherein the CdS layer 150 is disposed between the second electrically conductive layer 160 and the n-type absorber layer 110, and a support 170. The second electrically conductive layer 160 may comprise n-type TCO, for example, and is disposed between the support 170 and the CdS layer 150.

The PV device 100 schematically depicted in FIG. 2 is a superstrate-based device. Namely, the PV device 100 depicted in FIG. 2 is manufactured by performing a number of processing steps (described below), beginning with the substrate (support) 170. Consequentially, the substrate 170 is subjected to a number of high temperature processing steps during the manufacture of the PV device. For the arrangement shown in FIG. 2, the superstrate-based PV device 100 further includes a support 170. As indicated in FIG. 2, the second electrically conductive layer 160 is disposed between the support 170 and the window layer 150.

Similarly, the PV device 100 schematically depicted in FIG. 4 is a substrate-based device. Namely, for the substrate-based PV device 100 depicted in FIG. 4, the cover 190 may be affixed to the front contact 160 after the rest of the PV device 100 has been manufactured, such that the cover 190 has not been subjected to multiple high temperature semiconductor processing steps (which are described below). For the arrangement shown in FIG. 4, the substrate-based photovoltaic device 100 further includes a support 170. As indicated in FIG. 4, the first electrically conductive layer 140 is disposed between the support 170 and the p+-type semiconductor layer 130. In addition and as shown in FIG. 4, the substrate-based photovoltaic device 100 further includes a cover 190. As shown in FIG. 4, the second electrically conductive layer 160 is disposed between the cover 190 and the window layer 150.

The above described photovoltaic devices may be manufactured using a variety of semiconductor processing techniques. For example, the superstrate based PV devices shown in FIGS. 2 and 3 may be manufactured as follows. A first electrically conductive layer 160 may be deposited on a support 170 by any suitable technique, such as sputtering, chemical vapor deposition, spin coating, spray coating, or dip coating. Referring to FIG. 3, for certain configurations, an optional buffer layer 180 may be deposited on the second electrically conductive layer 160 by sputtering, followed by deposition of the second electrically conductive layer 160 on the buffer layer 180.

The window layer 150 may be then deposited on the second electrically conductive layer 160. Non-limiting examples of the deposition methods for window layer 150 include one or more of close-space sublimation (CSS), vapor transport method (VTM), sputtering, and electrochemical bath deposition (CBD). The absorber 110 may be deposited on the window layer 150 by employing one or more methods selected from close-space sublimation (CSS), vapor transport method (VTM), ion-assisted physical vapor deposition (IAPVD), radio frequency or pulsed magnetron sputtering (RFS or PMS), plasma enhanced chemical vapor deposition (PECVD), and electrochemical deposition (ECD). For certain configurations, the window layer may be deposited as a p-type or i-type semiconductor layer by varying one or more of the dopants, the thickness of the deposited layer, and post-deposition processing.

For configurations in which the absorber layer 110 is a p-type cadmium telluride layer, the absorber layer 110 may be treated with cadmium chloride, for example with a solution of CdCl₂ salt or with CdCl₂ vapor. The treatment with CdCl₂ is known to increase the carrier lifetime of the absorber layer 110 and may optionally be followed by an etching or rinsing step. For example, an acid etch may be performed. For other processes, the CdCl₂ may be rinsed off the surface, resulting in stoichiometric cadmium telluride at the interface, mainly removing the cadmium oxide and CdCl₂ residue from the surface, leaving a cadmium-to-tellurium ratio of about one (1) at the surface. The etching works by removing non-stoichiometric material that forms at the surface during processing. Other etching techniques known in the art that may result in a stoichiometric cadmium telluride at the interface may also be employed.

An interlayer 120 including a composition of manganese and tellurium is then deposited on the absorber layer 110 using one or more of the following techniques: sputtering, molecular beam epitaxy (MBE), evaporation, chemical bath deposition (CBD), metal-organic chemical vapor deposition (MOCVD), and atomic layer epitaxy (ALE). In particular, the CdMnTe composition can be achieved by using single source sputtering, or co-sputtering from CdTe and MnTe sources. A p+-type semiconductor layer 130 is then deposited over the interlayer 120. The deposition of the p+-type layer 130 may be achieved by depositing a p-type material using any suitable technique, for example PECVD or sputtering. Finally, the PV device may be completed by depositing an electrically conductive layer or a back contact layer 140, for example a metal layer.

Similarly, the substrate-based PV devices shown in FIG. 4 may be manufactured using processes, which (at a very high level) can be viewed as being the reverse-order process for forming a superstrate-based device. Namely, beginning with the cover (substrate) 180, an electrically conductive layer or a back contact layer 140, for example a metal layer, is deposited. Next, the p+-type layer 130 may be formed by depositing a p-type material using any suitable technique, for example PECVD or sputtering. The interlayer 120, absorber 110, window layer 150, and the second electrically conductive layer 160 may then be deposited using the techniques provided above. Last, the support layer 170 (which functions as a cover layer for this substrate-based configuration) may be attached to the stack using an adhesive, such as ethylene vinyl acetate (EVA). For particular configurations, a CIGS-type front contact may be employed. Namely, a relatively thin TCO layer with a metal grid may be deposited on a glass support layer 170 prior to disposing the support layer on the rest of the PV device. Similarly, the metal grid may be disposed on the glass support layer 170 prior to disposing the support layer on the rest of the PV device.

Beneficially, the use of the interlayer 120 may advantageously provide for an improved interface at the back-side of the CdTe absorber layer, reducing the recombination rate at that interface, providing a low recombining back contact for photovoltaic devices employing thin CdTe layers (for example having a thickness less than about 2 microns), while keeping the fill factor (FF) and open circuit voltage (Voc) high, thereby achieving higher efficiencies. Accordingly, the interlayer may advantageously facilitate the use of thinner CdTe layers in photovoltaic devices. The resulting PV devices may then be assembled in series to form a PV module (solar panel).

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A photovoltaic device comprising:
an absorber layer comprising a material comprising cadmium and tellurium;
a p+-type semiconductor layer; and
an interlayer interposed between the absorber layer and the p+-type semiconductor layer, wherein the interlayer comprises manganese.

2. The photovoltaic device of claim 1, wherein the interlayer further comprises tellurium.

3. The photovoltaic device of claim 2, wherein the interlayer comprises a composition having a formula (I):
Cd₁₋ₓMnₓTe, (I)
wherein “x” is in a range from about 0.01 to about 0.6.

4. The photovoltaic device of claim 3, wherein “x” is in a range from about 0.05 to about 0.44.

5. The photovoltaic device of claim 4, wherein “x” is in a range from about 0.10 to about 0.20.

6. The photovoltaic device of claim 1, wherein a percentage difference between a lattice constant of the absorber layer and a lattice constant of the interlayer is less than about one percent (1%).

7. The photovoltaic device of claim 1, wherein the interlayer has a band gap E_{g} in a range from about 1.6 eV to about 2.3 eV.

8. The photovoltaic device of claim 1, wherein the interlayer has a thickness in a range of about 20-200 nm.

9. The photovoltaic device of claim 1, wherein the interlayer comprises a p-doped manganese telluride or a p-doped cadmium manganese telluride.

10. The photovoltaic device of claim 1, wherein the absorber layer comprises a material selected from the group consisting of cadmium telluride, cadmium zinc telluride, cadmium sulfur telluride, cadmium manganese telluride, cadmium magnesium telluride and combinations thereof, and wherein the window layer (24) comprises a material selected from the group consisting of cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), amorphous or micro-crystalline silicon and Zn(O,H) and combinations thereof.

11. The photovoltaic device of claim 1, wherein the absorber layer comprises a p-type material and has a thickness less than about three (3) μm.

12. The photovoltaic device of claim 11, wherein the absorber layer has a thickness less than about two (2) μm.

13. The photovoltaic device of claim 1, further comprising a window layer, wherein the absorber layer is disposed between the window layer and the interlayer.

14. The photovoltaic device of claim 1, wherein the window layer comprises a material selected from the group consisting of cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), amorphous or micro-crystalline silicon and Zn(O,H) and combinations thereof.

15. The photovoltaic device of claim 1, wherein the p+-type semiconductor layer (130) comprises a p-type material selected from a group consisting of amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, (LaSr)CuOS, LaCuOSe_{0.6}Te_{0.4}, BiCuOSe, (BiCa)CuOSe, PrCuOSe, NdCuOS, Sr₂Cu₂ZnO₂S₂, Sr₂CuGaO₃S, (Ni,Zn,Co)₃O₄, and combinations thereof.

16. The photovoltaic device of claim 1, wherein the p+-type semiconductor layer comprises a p+ doped material selected from a group consisting of zinc telluride, magnesium telluride, manganese telluride, beryllium telluride, mercury telluride, arsenic telluride, antimony telluride, copper telluride, and combinations thereof.

17. The photovoltaic device of claim 16, wherein the p+ doped material further comprises a dopant selected from a group consisting of copper, gold, nitrogen, phosphorus, antimony, arsenic, silver, bismuth, sulfur, sodium, and combinations thereof.

18. The photovoltaic device of claim 1, further comprising a first electrically conductive layer, wherein the p+-type semiconductor layer is disposed between the first electrically conductive layer and the interlayer.

19. The photovoltaic device of claim 18, further comprising:
a window layer, wherein the absorber layer is disposed between the window layer and the interlayer; and
a second electrically conductive layer, wherein the window layer is disposed between the second electrically conductive layer and the absorber layer.

20. The photovoltaic device of claim 19, further comprising:
a support, wherein the second electrically conductive layer is disposed between the support and the window layer.

21. The photovoltaic device of claim 19, further comprising:
a support, wherein the first electrically conductive layer is disposed between the support and the p+-type semiconductor layer; and
a cover, wherein the second electrically conductive layer is disposed between the cover and the window layer.

22. The photovoltaic device of claim 1, wherein the absorber layer comprises an n-type material, the photovoltaic device further comprising:
a first electrically conductive layer, wherein the p+-type semiconductor layer is disposed between the first electrically conductive layer and the interlayer;
a semiconductor layer, wherein the absorber layer is disposed between the semiconductor layer and the interlayer;
a second electrically conductive layer, wherein the semiconductor layer is disposed between the second electrically conductive layer and the absorber layer; and
a support, wherein the second electrically conductive layer is disposed between the support and the semiconductor layer.

23. A photovoltaic device comprising:
an absorber layer comprising a material comprising cadmium and tellurium;
a p+-type semiconductor layer;
an interlayer interposed between the absorber layer and the p+-type semiconductor layer, wherein the interlayer comprises manganese and tellurium, and wherein the interlayer comprises a composition having a formula (I):
Cd₁₋ₓMnₓTe, (II)
wherein “x” is in a range from about 0.1 to about 0.6;
a first electrically conductive layer, wherein the p+-type semiconductor layer is disposed between the first electrically conductive layer and the interlayer;
a window layer, wherein the absorber layer is disposed between the window layer and the interlayer; and
a second electrically conductive layer, wherein the window layer is disposed between the second electrically conductive layer and the absorber layer.

24. The photovoltaic device of claim 23, wherein the absorber layer comprises a material selected from the group consisting of cadmium telluride, cadmium zinc telluride, cadmium sulfur telluride, cadmium manganese telluride, cadmium magnesium telluride and combinations thereof, and wherein the window layer (24) comprises a material selected from the group consisting of cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), amorphous or micro-crystalline silicon and Zn(O,H) and combinations thereof, and
wherein the window layer comprises a material selected from the group consisting of cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), amorphous or micro-crystalline silicon and Zn(O,H) and combinations thereof.

25. The photovoltaic device of claim 24, further comprising a support, wherein the second electrically conductive layer disposed between the support and the window layer.

26. The photovoltaic device of claim 24, further comprising:
a support, wherein the first electrically conductive layer is disposed between the support and the p+-type semiconductor layer; and
a cover, wherein the second electrically conductive layer is disposed between the cover and the window layer.
